(19) United States
(12) Patent Application Publication
(10) Pub. No.: US 2016/0380221 A1
(43) Pub. Date: Dec. 29, 2016

(54) PHOTOELECTRIC CONVERSION ELEMENT, WIRING BOARD FOR PHOTOELECTRIC CONVERSION ELEMENT, METHOD FOR MANUFACTURING PHOTOELECTRIC CONVERSION ELEMENT AND PHOTOELECTRIC CONVERSION STRUCTURE

(71) Applicant: Kabushiki Kaisha Toshiba, Minato-ku (JP)

(72) Inventors: Takeshi GOTANDA, Yokohama (JP); Shigehiko Mori, Kawasaki (JP); Mitsunaga Saito, Inzai (JP); Haruhi Cooka, Kawasaki (JP); Kenji Todori, Yokohama (JP); Hideyuki Nakao, Setagaya (JP); Satoshi Takayama, Kawasaki (JP)

(73) Assignee: Kabushiki Kaisha Toshiba, Minato-ku (JP)

(21) Appl. No.: 15/263,689

(22) Filed: Sep. 13, 2016

Related U.S. Application Data
(63) Continuation of application No. PCT/JP2015/068659, filed on Jun. 29, 2015.

(30) Foreign Application Priority Data
Sep. 5, 2014 (JP) 2014-181652

(51) Int. Cl. H01L 51/44; H01G 9/20; H01L 27/30; H01L 51/42; H01L 51/00

(52) U.S. Cl. CPC H01L 51/445; H01L 51/4253; H01L 51/0003; H01L 27/301; H01G 9/2018; H01G 9/2081; H01L 51/0043; H01L 51/0036; H01L 51/0047; H01L 51/0037

(57) ABSTRACT

According to one embodiment, a photoelectric conversion element includes a first interconnect, a second interconnect, a photoelectric conversion layer and an insulating layer. The second interconnect is separated from the first interconnect. The photoelectric conversion layer is provided between the first interconnect and the second interconnect. The insulating layer is arranged with the first interconnect. A face formed by the first interconnect and the insulating layer is substantially flat. The face contacts the photoelectric conversion layer.

### CROSS-REFERENCE TO RELATED APPLICATIONS

This is a continuation application of International Application PCT/JP2015/068659, filed on Jun. 29, 2015. This application also claims priority to Japanese Application No. 2014-181652, filed on Sep. 5, 2014. The entire contents of each are incorporated herein by reference.

### FIELD

Embodiments described herein relate generally to a photoelectric conversion element, a wiring board for a photoelectric conversion element, a method for manufacturing a photoelectric conversion element, and a photoelectric conversion structure.

### BACKGROUND

Solar cells, sensors, and the like using an organic photoelectric conversion material or a photoelectric conversion material containing an organic compound and an inorganic compound have been studied and developed. If solar cells and the like can be produced by applying or printing a photoelectric conversion material, there is a possibility that a device can be fabricated at relatively low cost.

In the case where a photoelectric conversion layer is formed by application, when an ink containing a photoelectric conversion material is applied onto an electrode, a thickness of the photoelectric conversion layer formed in an end portion of a foundation electrode is thinner than a thickness of the photoelectric conversion layer in a portion other than the end portion due to the flowing of the ink. The end portion of the electrode is a portion on which an electric field is concentrated. Due to this, when the thickness of the photoelectric conversion layer is relatively thin, a shunt resistance decreases so that the device characteristics may sometimes be deteriorated. It is desired to suppress the decrease in the shunt resistance in a photoelectric conversion element, a wiring board for a photoelectric conversion element, and a method for manufacturing a photoelectric conversion element.

### BRIEF DESCRIPTION OF THE DRAWINGS

FIGS. 1A to 1C are schematic views showing a photoelectric conversion element according to the embodiment;

FIGS. 2A to 2C are schematic plan views showing another photoelectric conversion element according to the embodiment;

FIGS. 3A to 3F are schematic views showing a method for manufacturing the photoelectric conversion element according to the embodiment;

FIGS. 4A to 4F are schematic views showing a method for manufacturing the photoelectric conversion element according to the embodiment;

FIGS. 5A to 5F are schematic views showing a method for manufacturing the photoelectric conversion element according to the embodiment; and

FIGS. 6A to 6C are schematic views showing a photoelectric conversion structure according to the embodiment.

### DETAILED DESCRIPTION

According to an embodiment, a photoelectric conversion element includes a first interconnect, a second interconnect, a photoelectric conversion layer and an insulating layer. The second interconnect is separated from the first interconnect. The photoelectric conversion layer is provided between the first interconnect and the second interconnect. The insulating layer is arranged with the first interconnect. A face formed by the first interconnect and the insulating layer is substantially flat. The face contacts the photoelectric conversion layer.

According to another embodiment, a wiring board for a photoelectric conversion element includes a first interconnect and an insulating layer. The insulating layer is arranged with the first interconnect. A face formed by the first interconnect and the insulating layer is substantially flat. A layer is formed later on the face.

According to another embodiment, a method for manufacturing a photoelectric conversion element is provided. The method includes forming a first interconnect, forming an insulating layer arranged with the first interconnect, and making a face formed by the first interconnect and the insulating layer substantially flat. The face is to contact a photoelectric conversion layer. The method includes forming the photoelectric conversion layer on the face, and forming a second interconnect on the photoelectric conversion layer.

According to another embodiment, a photoelectric conversion structure includes a plurality of photoelectric conversion elements. Each of the photoelectric conversion elements includes a first interconnect, a second interconnect, a photoelectric conversion layer, and an insulating layer. The second interconnect is separated from the first interconnect. The photoelectric conversion layer is provided between the first interconnect and the second interconnect. The insulating layer is arranged with the first interconnect. A face formed by the first interconnect and the insulating layer is substantially flat. The face contacts the photoelectric conversion layer. The photoelectric conversion elements are connected in series to each other.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

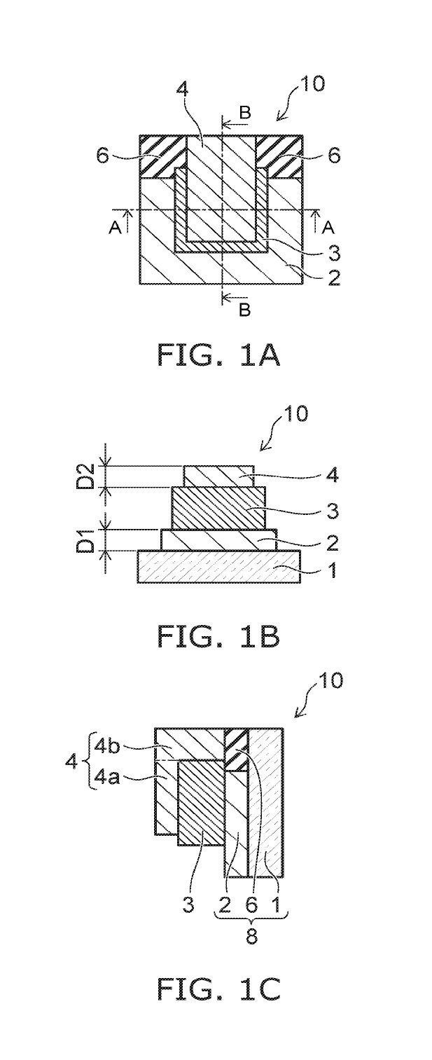

FIGS. 1A to 1C are schematic views showing a photoelectric conversion element according to the embodiment.

FIG. 1A is a schematic plan view showing the photoelectric conversion element according to the embodiment. FIG. 1B is a schematic cross-sectional view in a cross section A-A shown in FIG. 1A. FIG. 1C is a schematic cross-sectional view in a cross section B-B shown in FIG. 1A.

A photoelectric conversion element 10 according to the embodiment includes a wiring board 8, a photoelectric conversion layer 3, and a second interconnect 4. The wiring board 8 includes a substrate 1, a first interconnect 2, and an insulating layer 6. However, the wiring board 8 may not necessarily include the substrate 1. Examples of the photoelectric conversion element 10 according to the embodiment include a solar cell and a sensor. The photoelectric conversion layer 3 is formed by application and contains at least one of a material of an organic semiconductor or a material having a perovskite structure.

As shown in FIG. 1B, the second interconnect 4 is provided spaced from the substrate 1. The first interconnect 2 is provided between the substrate 1 and the second interconnect 4. The photoelectric conversion layer 3 is provided between the first interconnect 2 and the second interconnect 4.

As shown in FIG. 1C, the second interconnect 4 includes a first portion 4a and a second portion 4b. The first portion 4a is provided on the photoelectric conversion layer 3. The second portion 4b extends from the first portion 4a to the insulating layer 6. The insulating layer 6 is provided side by side with the first interconnect 2, and includes a portion provided between the substrate 1 and the second portion 4b of the second interconnect 4.

Between the first interconnect 2 and the photoelectric conversion layer 3, a first buffer layer (not shown) may be provided. Between the first portion 4a of the second interconnect 4 and the photoelectric conversion layer 3, a second buffer layer (not shown) which is different from the first buffer layer may be provided.

Either one of the first interconnect 2 and the second interconnect 4 becomes an anode. The other one of the first interconnect 2 and the second interconnect 4 becomes a cathode. Electricity is extracted from the first interconnect 2 and the second interconnect 4. The photoelectric conversion layer 3 is excited by light incident through the substrate 1 and the first interconnect 2 or light incident through the second interconnect 4, and electrons are generated in either one of the first interconnect 2 and the second interconnect 4, and holes are generated in the other one of the first interconnect 2 and the second interconnect 4.

As shown in FIG. 1C, a face which is formed by the first interconnect 2 and the insulating layer 6 and is in contact with the photoelectric conversion layer 3 is substantially flat.

In the specification of the application, the “substantially flat” refers to a structural change with respect to a layer to be formed later by application in a given place to such an extent that the shape in the place is not reflected. More preferably, a maximum height Rz of the face formed by the first interconnect 2 and the insulating layer 6 is preferably not more than 10% with respect to the thickness of the photoelectric conversion layer 3. The “maximum height Rz” refers to an interval between a peak and a bottom with respect to a standard length.

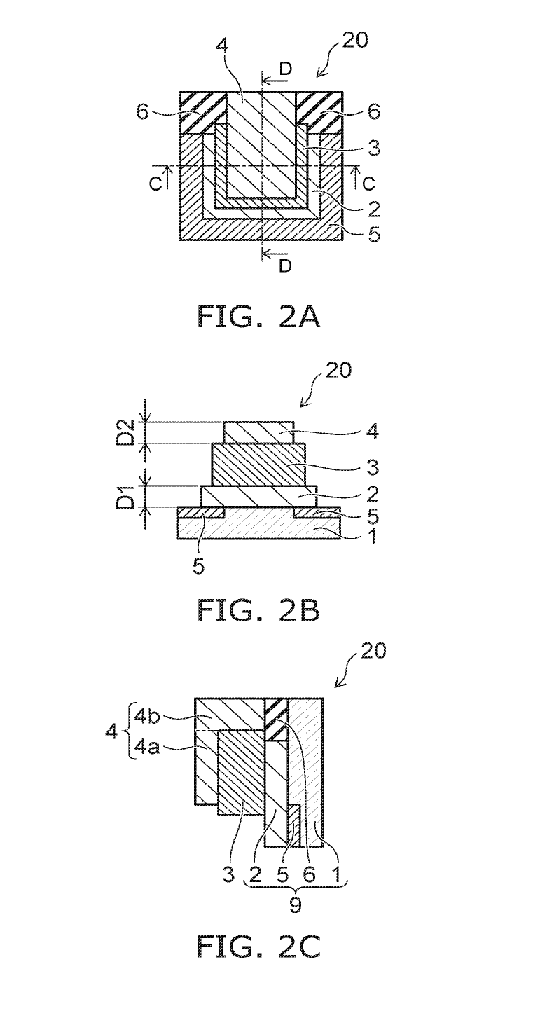

FIGS. 2A to 2C are schematic plan views showing another photoelectric conversion element according to the embodiment.

FIG. 2A is a schematic plan view showing another photoelectric conversion element according to the embodiment. FIG. 2B is a schematic cross-sectional view in a cross section C-C shown in FIG. 2A. FIG. 2C is a schematic cross-sectional view in a cross section D-D shown in FIG. 2A.

A photoelectric conversion element 20 shown in FIGS. 2A to 2C further includes a third interconnect (another interconnect) 5 as compared with the photoelectric conversion element 10 described above with respect to FIGS. 1A to 1C. The third interconnect 5 is provided on a substrate 1. The third interconnect 5 includes a portion provided between the substrate 1 and a first interconnect 2. The first interconnect 2 includes a portion provided between the third interconnect 5 and a photoelectric conversion layer 3. A face which is formed by the substrate 1 and the third interconnect 5 and is in contact with the first interconnect 2 is substantially flat. That is, as shown in FIGS. 2B and 2C, the third interconnect 5 is buried in the substrate 1. A wiring board 9 included in the photoelectric conversion element 20 further includes the third interconnect 5.

A part of the first interconnect 2 is provided on the third interconnect 5. In other words, the third interconnect 5 is provided between the substrate 1 and the part of the first interconnect 2.

In the photoelectric conversion element 20, a face which is formed by the first interconnect 2 and an insulating layer 6 and is in contact with the photoelectric conversion layer 3 is substantially flat. The other structure is the same as the structure of the photoelectric conversion element 10 described above with respect to FIGS. 1A to 1C.

Hereinafter, the constituent members of the photoelectric conversion element according to the embodiment will be described.

(Substrate 1)

The substrate 1 supports the other constituent members (the constituent members other than the substrate 1). The substrate 1 can form an electrode. As the substrate 1, a substrate which is not altered by heat or an organic solvent is preferred. As a material of the substrate 1, for example, an inorganic material, a plastic, a polymer film, a metal substrate, or the like is used. Examples of the inorganic material include a non-alkali glass and quartz glass. Examples of a material of the plastic and the polymer film include polyethylene, polyethylene terephthalate (PET), polyethylene naphthalate (PEN), polyimide, polyamide, polyamideimide, a liquid crystal polymer, and a cycloolefin polymer. Examples of a material of the metal substrate include stainless steel (SUS) and silicon.

As the substrate 1, a transparent substrate is used in the case where it is disposed on a light incident side. That is, in the case where the substrate 1 is disposed on a light incident side, as a material of the substrate 1, a material having light transmission properties is used. In the case where an electrode (the second interconnect 4 in the embodiment) on an opposite side of the substrate 1 is transparent or semi-transparent, as the substrate 1, a substrate which is not transparent may be used. A thickness of the substrate 1 is not particularly limited as long as the substrate 1 has a sufficient strength for supporting the other constituent members.

In the case where the substrate 1 is disposed on a light incident side, for example, by placing an anti-reflective film having a moth-eye structure on a light incident surface, light is efficiently taken in, and the energy conversion efficiency of the cell can be improved. The moth-eye structure has a regular projection array of about 100 nanometers (nm) on a surface. By the projection structure of the moth-eye structure, the refractive index in a thickness direction changes continuously. Due to this, by interposing a non-reflective film, a surface on which the refractive index changes discontinuously can be reduced. According to this, the reflection of light is reduced, and the cell efficiency is improved.

(First Interconnect 2 and Second Interconnect 4)

In the description with respect to the first interconnect 2 and the second interconnect 4, when simply referring to “interconnect”, it refers to at least one of the first interconnect 2 or the second interconnect 4.

The first interconnect 2 and the second interconnect 4 are not particularly limited as long as they have conductivity. As a material of the interconnect on a light transmitting side (for example, the first interconnect 2), a material which is transparent or semi-transparent and has conductivity is used. The first interconnect 2 and the second interconnect 4 are formed by a vacuum deposition method, a sputtering method, an ion plating method, a plating method, a coating method, or the like. Examples of the material of the interconnect which is transparent or semi-transparent include conductive metal oxides and semi-transparent metals. Specifically, as the material of the interconnect which is transparent or semi-transparent, a conductive glass, gold, platinum, silver, copper, or the like is used. Examples of a material of the conductive glass include indium oxide, zinc oxide, tin oxide, and complexes thereof such as indium tin oxide (ITO), fluorine-doped tin oxide (FTO), and indium zinc oxide. For example, the interconnect is fabricated as a film (NESA or the like) or a layer containing a conductive glass. As the material of the interconnect, for example, ITO or FTO is preferred. The material of the interconnect may be polyaniline and a derivative thereof, polythiophene and a derivative thereof, and the like, which are organic conductive polymers.

In the case where the material of the interconnect is ITO, a thickness of the interconnect is preferably not less than 30 nm and not more than 300 nm. When the thickness of the interconnect is thinner than 30 nm, the conductivity decreases, and the resistance increases. The decrease in the conductivity is one of the causes of a decrease in photoelectric conversion efficiency. When the thickness of the interconnect is made thicker than 300 nm, the flexibility of ITO decreases. If the flexibility of ITO decreases, ITO may sometimes crack when stress acts thereon.

A sheet resistance of the interconnect is preferably as low as possible, and is preferably not more than 10Ω/□. The interconnect may be a single layer or may have a structure in which layers containing materials having different work functions are stacked.

In the case where the interconnect is formed in contact with an electron transport layer, it is preferred to use a material having a low work function as the material of the interconnect. Examples of the material having a low work function include alkali metals and alkaline earth metals. Specific examples of the material having a low work function can include Li, In, Al, Ca, Mg, Sm, Tb, Yb, Zr, Na, K, Rb, Cs, Ba, and alloys thereof. The interconnect may be a single layer or may have a structure in which layers containing materials having different work functions are stacked. Further, the material of the interconnect may be an alloy of at least one of the above-mentioned materials having a low work function and at least one of gold, silver, platinum, copper, manganese, titanium, cobalt, nickel, tungsten, or tin. Examples of the alloy include a lithium-aluminum alloy, a lithium-magnesium alloy, a lithium-indium alloy, a magnesium-silver alloy, a calcium-indium alloy, a magnesium-aluminum alloy, an indium-silver alloy, and a calcium-aluminum alloy.

In the case where the interconnect is formed in contact with an electron transport layer, the thickness of the interconnect is preferably not less than 1 nm and not more than 500 nm. The thickness of the interconnect is more preferably not less than 10 nm and not more than 300 nm. In the case where the thickness of the interconnect is thinner than 1 nm, as compared with the case where the thickness of the interconnect is not less than 1 nm, the resistance increases, and generated charges cannot be sufficiently transmitted to an external circuit in some cases. In the case where the thickness of the interconnect is thicker than 500 nm, it takes a relatively long time for forming the interconnect. Due to this, the temperature of the material increases, and the other materials may be damaged to deteriorate the performance in some cases. Further, since the material is used in a large amount, an occupancy time of a device for forming the interconnect (for example, a film formation device) is prolonged, resulting in increasing the cost.

In the case where the interconnect is formed in contact with a hole transport layer, it is preferred to use a material having a high work function as the material of the interconnect. Examples of the material having a high work function include Au, Ag, Cu, and alloys thereof. The interconnect may be a single layer or may have a structure in which layers containing materials having different work functions are stacked.

In the case where the interconnect is formed in contact with a hole transport layer, the thickness of the interconnect is preferably not less than 1 nm and not more than 500 nm. The thickness of the interconnect is more preferably not less than 10 nm and not more than 300 nm. In the case where the thickness of the interconnect is thinner than 1 nm, as compared with the case where the thickness of the interconnect is not less than 1 nm, the resistance increases, and generated charges cannot be sufficiently transmitted to an external circuit in some cases. In the case where the thickness of the interconnect is thicker than 500 nm, it takes a relatively long time for forming the interconnect. Due to this, the temperature of the material increases, and the other materials may be damaged to deteriorate the performance in some cases. Further, since the material is used in a large amount, an occupancy time of a device for forming the interconnect (for example, a film formation device) is prolonged, resulting in increasing the cost.

As shown in FIGS. 1B and 2B, in the case where the material of the first interconnect 2 and the material of the second interconnect 4 are ITO, a thickness D1 of the first interconnect 2 may be thicker than a thickness D2 of the second interconnect 4.

(Third Interconnect 5)

The third interconnect 5 is not particularly limited as long as it has conductivity. The third interconnect 5 becomes an auxiliary electrode which relaxes resistance loss in the first interconnect 2. Therefore, it is preferred that a sheet resistance of the third interconnect 5 is lower than a sheet resistance of the first interconnect 2. On the other hand, the transparency of the third interconnect 5 is relatively low. Due to this, in the case where a material which is transparent or semi-transparent and has conductivity is used as the material of the first interconnect 2, it is preferred that only a part of the first interconnect 2 is stacked on the third interconnect 5. Specific examples of a material of the third interconnect 5 can include gold, platinum, silver, copper, aluminum, Li, In, Al, Ca, Mg, Sm, Tb, Yb, Zr, Na, K, Rb, Cs, Ba, Mo, and alloys thereof. The third interconnect 5 may be a single layer or may have a structure in which layers containing materials having different work functions are stacked.

The thickness of the third interconnect 5 is preferably not less than 1 nm and not more than 500 nm. The thickness of the third interconnect 5 is more preferably not less than 10 nm and not more than 300 nm. In the case where the thickness of the third interconnect 5 is thinner than 1 nm, as compared with the case where the thickness of the third interconnect 5 is not less than 1 nm, the resistance increases, and generated charges cannot be sufficiently transmitted to an external circuit in some cases. In the case where the thickness of the third interconnect 5 is thicker than 500 nm, it takes a relatively long time for forming the third interconnect 5. Due to this, the temperature of the material increases, and the other materials may be damaged to deteriorate the performance in some cases. Further, since the material is used in a large amount, an occupancy time of a device for forming the third interconnect 5 (for example, a film formation device) is prolonged, resulting in increasing the cost.

(Buffer Layer)

It is more preferred that a first buffer layer is provided between the first interconnect 2 and the photoelectric conversion layer 3. Further, it is more preferred that a second buffer layer which is different from the first buffer layer is provided between the first portion 4a of the second interconnect 4 and the photoelectric conversion layer 3. Either one of the first buffer layer and the second buffer layer is a hole transport layer. The other one of the first buffer layer and the second buffer layer is an electron transport layer.

As a material of the hole transport layer and the electron transport layer, a metal oxide or a halogen compound is exemplified.

Examples of the metal oxide include titanium oxide, molybdenum oxide, vanadium oxide, zinc oxide, nickel oxide, lithium oxide, calcium oxide, cesium oxide, and aluminum oxide.

Examples of the halogen compound include LiF, LiCl, LiBr, LiI, NaF, NaCl, NaBr, NaI, KF, KCl, KBr, KI, and CsF. More preferred examples of the halogen compound include LiF.

As a material of the hole transport layer, a polythiophene-based polymer such as PEDOT: PSS (poly(3,4-ethylenedioxythiophene)-poly(styrenesulphonate)) or an organic conductive polymer such as polyaniline or polypyrrole can be used. Examples of a representative product of the polythiophene-based polymer include Clevios PH500, Clevios PH, Clevios PV P Al 4083, and Clevios HIL1,1 of H.C. Starck GmbH. As an inorganic material, molybdenum oxide is exemplified.

In the case where Clevios PH500 is used as the material of the hole transport layer, the thickness of the hole transport layer is preferably not less than 20 nm and not more than 100 nm. In the case where the thickness of the hole transport layer is thinner than 20 nm, an effect of preventing a short circuit of a lower electrode (the first interconnect 2 in the embodiment) is decreased, and a short circuit occurs. In the case where the thickness of the hole transport layer is thicker than 100 nm, as compared with the case where the thickness of the hole transport layer is not more than 100 nm, the resistance increases, and a generated current is restricted. Due to this, the photoelectric conversion efficiency decreases. A method for forming the hole transport layer is not particularly limited as long as it is a method capable of forming a thin film. For example, it is possible to apply the material of the hole transport layer by spin coating or the like. After applying the material of the hole transport layer to a desired thickness, the material is dried by heating with a hot plate or the like. It is preferred that the applied material of the hole transport layer is dried by heating at 140° C. or higher and 200° C. or lower for not less than a few minutes and not more than about 10 minutes. As a solution to be applied, it is desired to use a solution previously filtered through a filter.

The electron transport layer has a function to efficiently transport electrons. Examples of a material of the electron transport layer include metal oxides. Examples of the metal oxides include amorphous titanium oxide obtained by hydrolysis of a titanium alkoxide using a sol-gel method.

A method for forming the electron transport layer is not particularly limited as long as it is a method capable of forming a thin film. Examples of the method for forming the electron transport layer include a spin coating method. In the case where titanium oxide is used as the material of the electron transport layer, the thickness of the electron transport layer is desirably not less than 5 nm and not more than 20 nm. In the case where the thickness of the electron transport layer is thinner than 5 nm, a hole block effect decreases. Due to this, generated excitons are inactivated before being dissociated into electrons and holes, and therefore, a current cannot be efficiently extracted. In the case where the thickness of the electron transport layer is thicker than 20 nm, as compared with the case where the thickness of the electron transport layer is not more than 20 nm, the resistance of the electron transport layer increases, and a generated current is restricted. Due to this, the photoelectric conversion efficiency decreases. As a solution to be applied, it is desired to use a solution previously filtered through a filter.

After applying the material of the electron transport layer to a specified thickness, the material is dried by heating using a hot plate or the like. The applied material of the electron transport layer is dried by heating at 50° C. or higher and 100° C. or lower for not less than a few minutes and not more than about 10 minutes while promoting hydrolysis in air. As an inorganic material, metal calcium or the like is exemplified.

(Photoelectric Conversion Layer 3)

As the photoelectric conversion layer 3, a heterojunction or a bulk heterojunction composed of an organic semiconductor can be used. The bulk heterojunction forms a micro layer separation structure by mixing a p-type semiconductor and an n-type semiconductor in the photoelectric conversion layer 3. This is generally called bulk heterojunction. The mixed p-type semiconductor and n-type semiconductor form a p-n junction of a nano-order size in the photoelectric conversion layer 3 to obtain a current by utilizing photocharge separation occurring on a junction interface. The p-type semiconductor contains a material having an electron-donating property. On the other hand, the n-type semiconductor contains a material having an electron-accepting property. In the embodiment, at least one of the p-type semiconductor or the n-type semiconductor may be an organic semiconductor.

As the p-type organic semiconductor, for example, polythiophene and a derivative thereof, polypyrrole and a derivative thereof, a pyrazoline derivative, an arylamine derivative, a stilbene derivative, a triphenyldiamine derivative, oligothiophene and a derivative thereof, polyvinylcarbazole and a derivative thereof, polysilane and a derivative thereof, a polysiloxane derivative having an aromatic amine in a side chain or a main chain, polyaniline and a derivative thereof, a phthalocyanine derivative, porphyrin and a derivative thereof, polyphenylenevinylene and a derivative thereof, polythienylenevinylene and a derivative thereof, etc. can be used, and these may be used in combination. Further, a copolymer thereof may be used. Examples of the copolymer include a thiophene-fluorene copolymer and a phenylene ethynylene-phenylene vinylene copolymer.

As the p-type organic semiconductor, polythiophene which is a conductive polymer having a π conjugation and a derivative thereof are preferred. The polythiophene and a derivative thereof can ensure relatively excellent tacticity. The solubility of the polythiophene and a derivative thereof in a solvent is relatively high. The polythiophene and a derivative thereof are not particularly limited as long they are compounds having a thiophene skeleton. Specific examples of the polythiophene and a derivative thereof include polyalkylthiophene; polyarylthiophene such as poly-3-phenylthiophene; polyalkylisothionaphthene such as poly-3-butylisothionaphthene; and polyethylenedioxythiophene. Examples of the polyalkylthiophene and poly-3-phenylthiophene include poly-3-methylthiophene, poly-3-butylthiophene, poly-3-hexylthiophene, poly-3-octylthiophene, poly-3-decylthiophene, and poly3-dodecylthiophene. Examples of the polyarylthiophene and poly-3-butylisothionaphthene include poly-3-(p-alkylphenylthiophene). Examples of the polyalkylisothionaphthene and polyethylened ioxythiophene include poly-3-hexylisothionaphthene, poly-3-octylisothiona phthene, and poly-3-decylisothionaphthene.

Further, a derivative such as PCDTBT (poly[N-9″-hepta-decanyl-2,7-carbazole-alt-5,5-(4′,T-di-2-thien yl-2′,1′,3′-benzothiadiazole)]) which is a copolymer containing carbazole, benzothiadiazole, and thiophene is known as a compound capable of obtaining relatively excellent photoelectric conversion efficiency.

These conductive polymers can be each formed as a film or a layer by applying a solution in which such a polymer is dissolved in a solvent. Therefore, an organic thin-film solar cell having a large area can be manufactured by a printing method or the like in an inexpensive facility at low cost.

As the n-type organic semiconductor, a fullerene and a derivative thereof are preferred. The fullerene derivative to be used here is not particularly limited as long as it is a derivative having a fullerene skeleton. Specific examples thereof include derivatives constituted by using C₆₀, C₇₀, C₇₆, C₇₈, C₈₄, or the like as a basic skeleton. The fullerene derivative may be a derivative in which carbon atoms in the fullerene skeleton are modified with arbitrary functional groups, and the functional groups may be combined with each other to form a ring. In the fullerene derivative, a fullerene-bonded polymer is included. A fullerene derivative which has a functional group with high affinity for a solvent and has high solubility in a solvent is preferred.

Examples of the functional group in the fullerene derivative include a hydrogen atom; a hydroxy group; a halogen atom such as a fluorine atom; an alkyl group such as a methyl group; an alkenyl group; a cyano group; an alkoxy group such as a methoxy group; an aromatic hydrocarbon group such as a phenyl group; and an aromatic heterocyclic group such as a thienyl group. Examples of the halogen atom include a chlorine atom. Examples of the alkyl group include an ethyl group. Examples of the alkenyl group include a vinyl group. Examples of the alkoxy group include an ethoxy group. Examples of the aromatic hydrocarbon group include a naphthyl group. Examples of the aromatic heterocyclic group include a pyridyl group. Specific examples thereof include hydrogenated fullerenes such as C₆₀H₃₆ and C₇₀H₃₆, oxide fullerenes such as C₆₀ and C₇₀, and fullerene metal complexes.

It is more preferred to use 60PCBM ([6,6]-phenyl-C₆₁ methyl butyrate) or 70PCBM ([6,6]-phenyl-C₇₁-methyl butyrate) as the fullerene derivative among those described above.

When an unmodified fullerene is used as the n-type organic semiconductor, it is preferred to use C₇₀. The generation efficiency of photocarriers of a fullerene C₇₀ is relatively high. It is preferred to use a fullerene C₇₀ in an organic thin-film solar cell.

In the photoelectric conversion layer 3, a mixing ratio between the n-type organic semiconductor and the p-type organic semiconductor is preferably approximately as follows: n-type organic semiconductor: p-type organic semiconductor=1:1 in the case where the p-type semiconductor is a P3AT-based semiconductor. Further, a mixing ratio between the n-type organic semiconductor and the p-type organic semiconductor is preferably approximately as follows: n-type organic semiconductor: p-type organic semiconductor=4:1 in the case where the p-type semiconductor is a PCDTBT-based semiconductor.

In order to apply the organic semiconductor, it is necessary to dissolve the organic semiconductor in a solvent. Examples of the solvent to be used here include unsaturated hydrocarbon-based solvents, halogenated aromatic hydrocarbon-based solvents, halogenated saturated hydrocarbon-based solvents, and ethers. Examples of the unsaturated hydrocarbon-based solvents include toluene, xylene, tetralin, decalin, mesitylene, n-butylbenzene, sec-butylbenzene, and tert-butylbenzene. Examples of the halogenated aromatic hydrocarbon-based solvents include chlorobenzene, dichlorobenzene, and trichlorobenzene. Examples of the halogenated saturated hydrocarbon-based solvents include carbon tetrachloride, chloroform, dichloromethane, dichloroethane, chlorobutane, bromobutane, chloropentane, chlorohexane, bromohexane, and chlorocyclohexane. Examples of the ethers include tetrahydrofuran and tetrahydropyran. Halogen-based aromatic solvents are more preferred. These solvents can be used alone or in admixture.

Examples of a method for forming a film or a layer by applying the solution include a spin coating method, a dip coating method, a casting method, a bar coating method, a roll coating method, a wire bar coating method, a spraying method, screen printing, a gravure printing method, a flexoprinting method, an offset printing method, gravure offset printing, dispenser application, a nozzle coating method, a capillary coating method, and an inkjet method. These application methods can be used alone or in combination

As the photoelectric conversion layer 3, perovskite can be used. Perovskite can be represented by ABX₃ composed of an ion A, an ion B, and an ion X. When the ion B is smaller than the ion A, ABX₃ has a perovskite structure in some cases. The perovskite structure has a unit lattice of a cubic crystal system. In the perovskite structure, the ion A is disposed at each vertex of a cubic crystal, and the ion B is disposed at a body center, and the ion X is disposed at each face center of the cubic crystal centered on the ion B. A direction of a BX₆ octahedron is easily distorted by an interaction with the ion A. The BX₆ octahedron causes Mott transition due to a decrease in the symmetry. In the BX₆ octahedron, a valence electron localized in an ion M can extend as a band. The ion A is preferably CH₃NH₃. The ion B is preferably at least one of Pb or Sn. The ion X is preferably at least one of Cl, Br, or I. The material constituting each of the ion A, the ion B, and the ion X may be a simple substance or may be a mixture.

(Insulating Layer 6)

In the insulating layer 6, a polymer material, an oxide, or a halogen compound can be used.

Examples of the polymer material include polyethylene, polyvinyl chloride, EVA, polypropylene, polystyrene, an ABS resin, a methacrylic resin, polyacetal, tetrafluoroethylene, ionomer polyamide, polycarbonate, polyphenylene oxide, polysulfone, an urea resin, a phenol resin, a melamine resin, a polyester resin, an epoxy resin, cellulose acetate, a silicone resin, a urethane resin, and polyimide. However, the polymer material is not limited only thereto.

Specific examples of the oxide include titanium oxide, molybdenum oxide, vanadium oxide, zinc oxide, nickel oxide, lithium oxide, calcium oxide, cesium oxide, aluminum oxide, and silicon oxide.

Examples of the halogen compound include LiF, LiCl, LiBr, LiI, NaF, NaCl, NaBr, NaI, KF, KCl, KBr, KI, and CsF. More preferred examples of the halogen compound include LiF.

The wettability of the first interconnect 2 to a semiconductor solution may be higher than the wettability of the insulating layer to the semiconductor solution. The “wettability” shows the affinity (a property to be easily adhered) of a liquid for a solid surface. For example, the wettability is evaluated based on the magnitude of the contact angle in some cases.

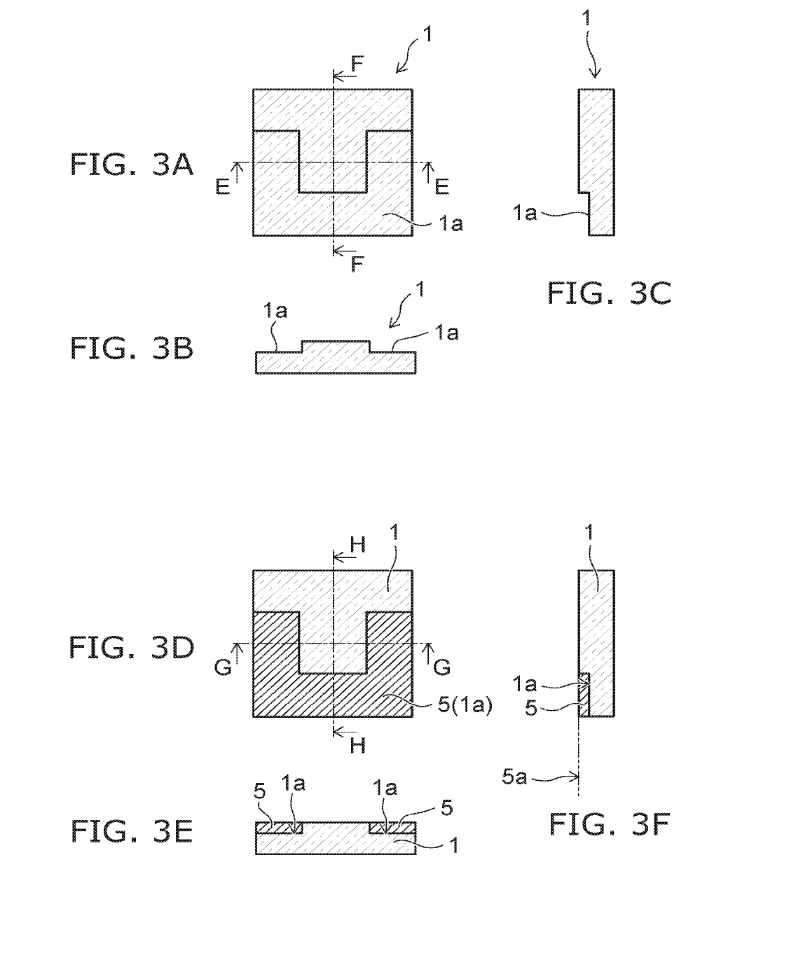

FIGS. 3A to 5F are schematic views describing a method for manufacturing the photoelectric conversion element according to the embodiment.

FIG. 3A is a schematic plan view showing the substrate 1 of the embodiment. FIG. 3B is a schematic cross-sectional view in a cross section E-E shown in FIG. 3A. FIG. 3C is a schematic cross-sectional view in a cross section F-F shown in FIG. 3A.

FIG. 3D is a schematic plan view describing a method for forming the third interconnect 5 of the embodiment. FIG. 3E is a schematic cross-sectional view in a cross section G-G shown in FIG. 3D. FIG. 3F is a schematic cross-sectional view in a cross section H-H shown in FIG. 3D.

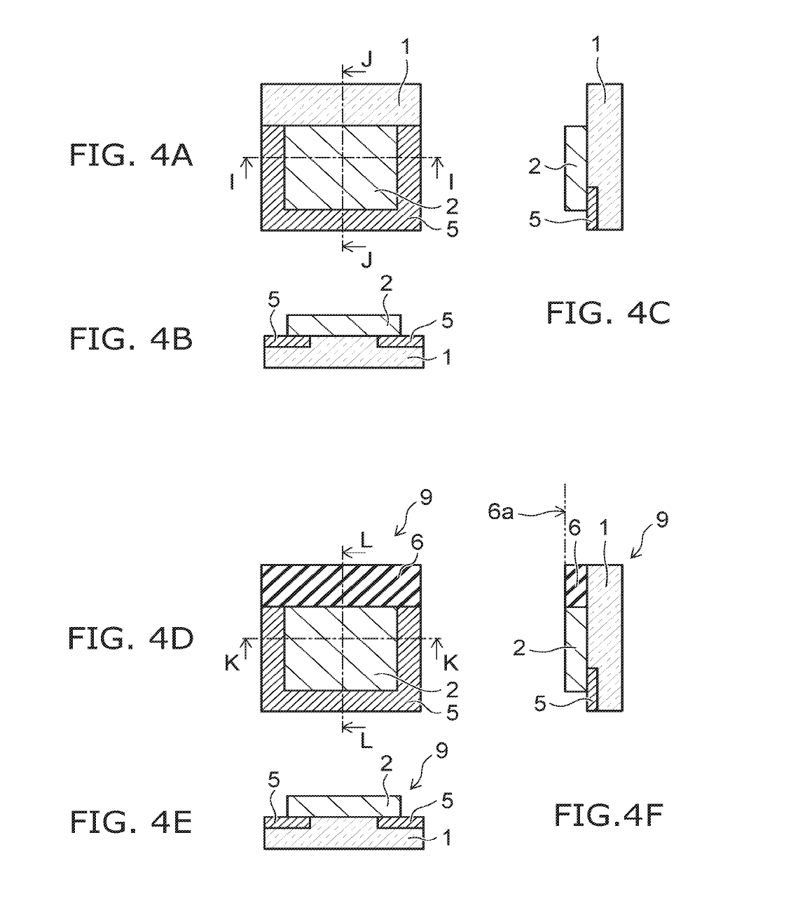

FIG. 4A is a schematic plan view describing a method for forming the first interconnect 2 of the embodiment. FIG. 4B is a schematic cross-sectional view in a cross section I-I shown in FIG. 4A. FIG. 4C is a schematic cross-sectional view in a cross section J-J shown in FIG. 4A.

FIG. 4D is a schematic plan view describing a method for forming the insulating layer 6 of the embodiment. FIG. 4E is a schematic cross-sectional view in a cross section K-K shown in FIG. 4D. FIG. 4F is a schematic cross-sectional view in a cross section L-L shown in FIG. 4D.

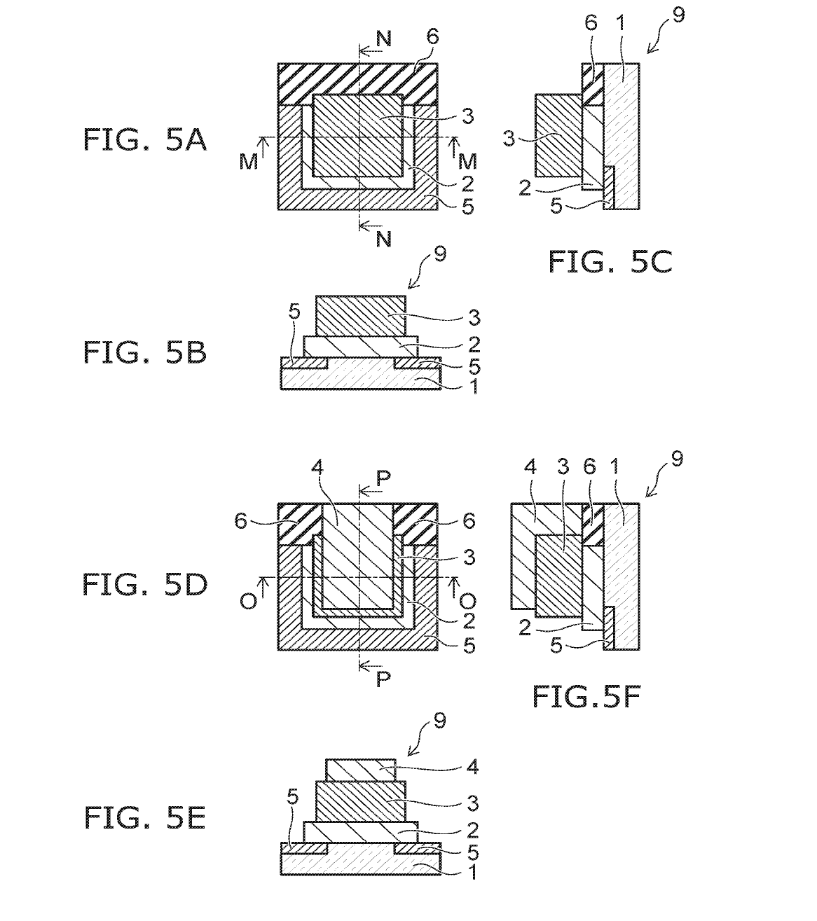

FIG. 5A is a schematic plan view describing a method for forming the photoelectric conversion layer 3 of the embodiment. FIG. 5B is a schematic cross-sectional view in a cross section M-M shown in FIG. 5A. FIG. 5C is a schematic cross-sectional view in a cross section N-N shown in FIG. 5A.

FIG. 5D is a schematic plan view describing a method for forming the second interconnect 4 of the embodiment. FIG. 5E is a schematic cross-sectional view in a cross section O-O shown in FIG. 5D. FIG. 5F is a schematic cross-sectional view in a cross section P-P shown in FIG. 5D.

In the embodiment, as the substrate 1, a glass plate can be used. As the first interconnect 2, ITO can be used. As the insulating layer 6, SiO₂ can be used. As the third interconnect 5, Au can be used.

As shown in FIGS. 3A to 3C, an engraved portion 1a is formed in the glass plate (substrate 1) by etching. Subsequently, as shown in FIGS. 3D to 3F, Au is formed in the engraved portion 1a of the glass plate. At this time, as shown in FIG. 3F, a face 5a formed by the substrate 1 and the third interconnect 5 is substantially flat. On the face 5a, the first interconnect 2 and the insulating layer 6 are formed later.

As shown in FIGS. 4A to 4C, ITO (first interconnect 2) is formed by sputtering in a place to be in contact with the glass plate and the third interconnect 5. Subsequently, as shown in FIGS. 4D to 4F, SiO₂ is formed by sputtering as the insulating layer 6. At this time, as shown in FIG. 4F, a face 6a formed by the first interconnect 2 and the insulating layer 6 is substantially flat. On the face 6a, the photoelectric conversion layer 3 is formed later.

In this manner, the wiring board 9 described above with respect to FIGS. 2A to 2C is manufactured.

In the embodiment, by using the wiring board 9 described above with respect to FIGS. 3A to 4F, the photoelectric conversion element 20 described above with respect to FIGS. 2A to 2C is fabricated. As a material of the p-type organic semiconductor of the photoelectric conversion layer 3, PTB7 can be used. As a material of the n-type organic semiconductor of the photoelectric conversion layer 3, a bulk heterojunction of [70]PCBM can be used. As the second interconnect 4, AgMg can be used. Between the ITO (first interconnect 2) and the photoelectric conversion layer 3, PEDOT:PSS can be used as the first buffer layer. Between the AgMg (second interconnect 4) and the photoelectric conversion layer 3, LiF can be used as the second buffer layer.

As shown in FIGS. 5A to 5C, PEDOT:PSS is formed by spin coating as the first buffer layer on the wiring board 9 described above with respect to FIGS. 3A to 4F. Subsequently, the material is dried at 120° C. for 10 minutes. Subsequently, the photoelectric conversion layer 3 is formed by spin coating with a solution containing PTB7 and [70]PCBM. The mass ratio between PTB7 and [70]PCBM is adjusted as follows: PTB7:[70]PCBM=1:2. As a dissolving solution, CB containing 3% DIO is utilized.

Subsequently, LiF of 0.02 nm is formed as the second buffer layer by a vapor deposition device. The film thickness of LiF (an indicated value of a film thickness meter of the vapor deposition device) formed here is smaller than the diameter of the Li atom (0.34 nm). It is unlikely to be a continuous film, and the value means an average film thickness.

Subsequently, as shown FIGS. 5D to 5F, AgMg (Mg: 90 wt %) of 100 nm is formed as the second interconnect 4.

In this manner, the photoelectric conversion element 20 described above with respect to FIGS. 2A to 2C is manufactured.

According to the embodiment, the face 6a which is formed by the first interconnect 2 and the insulating layer 6 and is in contact with the photoelectric conversion layer 3 is substantially flat. According to this, the decrease in the shunt resistance can be suppressed, and the current leakage can be suppressed. In addition, the photoelectric conversion efficiency of the photoelectric conversion element according to the embodiment can be improved.

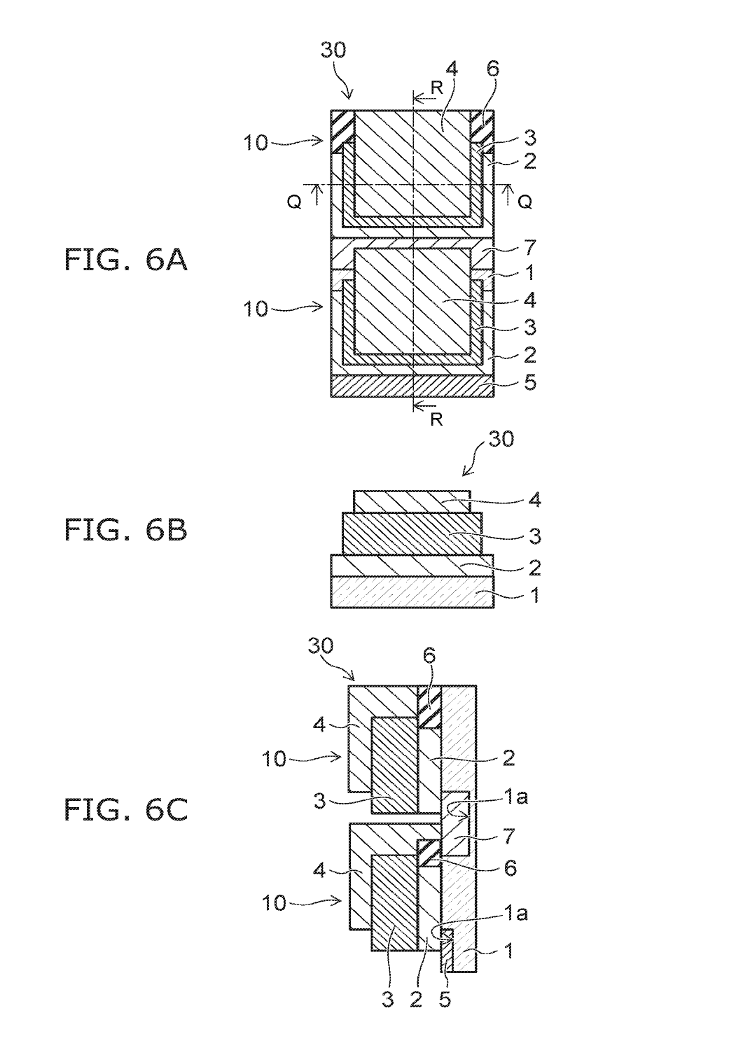

FIGS. 6A to 6C are schematic views showing a photoelectric conversion structure according to the embodiment.

A photoelectric conversion structure 30 shown in FIGS. 6A to 6C has a structure in which a plurality of photoelectric conversion elements 10 is connected in series to each other. As the substrate 1, a glass plate can be used. As the first interconnect 2, ITO can be used. As the insulating layer 6, S10₂ can be used. As the third interconnect 5, a stacked body of Mo (10 nm)/Al (130 nm)/Mo (10 nm) can be used.

The photoelectric conversion structure 30 shown in FIGS. 6A to 6C includes a fourth interconnect 7. The fourth interconnect 7 is provided on the substrate 1. A face which is formed by the substrate 1 and the fourth interconnect 7 and is in contact with the first interconnect 2 is substantially flat. That is, as shown in FIGS. 6B and 6C, the fourth interconnect 7 is buried in the substrate 1. The fourth interconnect 7 links the plurality of photoelectric conversion elements 10 to each other. In other words, the fourth interconnect 7 electrically connects the plurality of photoelectric conversion elements 10 to each other. As the fourth interconnect 7, ITO can be used.

As a material of the p-type organic semiconductor of the photoelectric conversion layer 3, PTB7 can be used. As a material of the n-type organic semiconductor of the photoelectric conversion layer 3, a bulk heterojunction of [70]PCBM can be used. As the second interconnect 2, AgMg can be used. Between the ITO (first interconnect 2) and the photoelectric conversion layer 3, PEDOT:PSS can be used as the first buffer layer. Between the AgMg (second interconnect 4) and the photoelectric conversion layer 3, LiF can be used as the second buffer layer.

As shown in FIG. 6C, an engraved portion 1a is formed in the glass plate (substrate 1) by etching. In the engraved portion 1a to serve as a portion which links the plurality of photoelectric conversion elements 10 to each other, ITO is formed by sputtering as the fourth interconnect 7. In the engraved portion 1a to serve as a portion which does not link the plurality of photoelectric conversion elements 10 to each other, a stacked body of Mo (10 nm)/Al (130 nm)/Mo (10 nm) is formed by vacuum deposition as the third interconnect 5.

Subsequently, ITO is formed by sputtering as the first interconnect 2 in a place to be in contact with the glass plate and the third interconnect 5 and in a place to be in contact with the glass plate and the fourth interconnect 7. Subsequently, SiO₂ is formed by sputtering as the insulating layer 6. Subsequently, PEDOT:PSS is formed by spin coating as the first buffer layer. The PEDOT:PSS present on the ITO (fourth interconnect 7) as the linking portion can be removed by wiping.

Subsequently, the material is dried at 120° C. for 10 minutes. Subsequently, the photoelectric conversion layer 3 is formed by spin coating with a solution containing PTB7 and [70]PCBM. The mass ratio between PTB7 and [70]PCBM is adjusted as follows: PTB7:[70]PCBM=1:2. As a dissolving solution, CB containing 3% DIO is utilized. The photoelectric conversion layer 3 present on the ITO (fourth interconnect 7) as the linking portion can be removed by wiping.

Subsequently, LiF of 0.02 nm is formed as the second buffer layer by a vapor deposition device. The film thickness of LiF (an indicated value of a film thickness meter of the vapor deposition device) formed here is smaller than the diameter of the Li atom (0.34 nm). It is unlikely to be a continuous film, and the value means an average film thickness.

Subsequently, AgMg (Mg: 90 wt %) of 100 nm is formed as the second interconnect 4. As shown in FIG. 6C, the AgMg to be linked to the photoelectric conversion element 10 is formed so as to be connected with the ITO (fourth interconnect 7) as the linking portion.

According to the embodiment, a photoelectric conversion element, a wiring board for a photoelectric conversion element, a method for manufacturing a photoelectric conversion element, and a photoelectric conversion structure, each capable of suppressing the decrease in the shunt resistance, can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A photoelectric conversion element comprising:
a first interconnect;
a second interconnect separated from the first interconnect;
a photoelectric conversion layer provided between the first interconnect and the second interconnect; and
an insulating layer arranged with the first interconnect,
a face formed by the first interconnect and the insulating layer being substantially flat, the face contacting the photoelectric conversion layer.

2. The element according to claim 1, further comprising a third interconnect,
a portion of the first interconnect being provided on the third interconnect.

3. The element according to claim 1, wherein a thickness of the first interconnect is thicker than a thickness of the second interconnect.

4. The element according to claim 1, wherein wettability of the first interconnect to a semiconductor solution is higher than wettability of the insulating layer to the semiconductor solution.

5. The element according to claim 1, the element further comprising:
a first buffer layer provided between the first interconnect and the photoelectric conversion layer; and
a second buffer layer provided between the second interconnect and the photoelectric conversion layer.

6. The element according to claim 2, wherein a sheet resistance of the third interconnect is lower than a sheet resistance of the first interconnect.

7. A wiring board for a photoelectric conversion element, comprising:
a first interconnect; and
an insulating layer arranged with the first interconnect,
a face formed by the first interconnect and the insulating layer being substantially flat, a layer being formed later on the face.

8. The board according to claim 7, further comprising an other interconnect different from the first interconnect,
a part of the first interconnect being provided on the other interconnect.

9. The board according to claim 7, wherein wettability of the first interconnect to a semiconductor solution is higher than wettability of the insulating layer to the semiconductor solution.

10. A method for manufacturing a photoelectric conversion element, comprising:
forming a first interconnect;
forming an insulating layer arranged with the first interconnect, and making a face formed by the first interconnect and the insulating layer substantially flat, the face being to contact a photoelectric conversion layer;
forming the photoelectric conversion layer on the face; and
forming a second interconnect on the photoelectric conversion layer.

11. The method according to claim 10, further comprising forming a third interconnect,
a part of the first interconnect being formed on the third interconnect in the forming the first interconnect.

12. The method according to claim 10, wherein a thickness of the first interconnect is made thicker than a thickness of the second interconnect.

13. The method according to claim 10, wherein the method further comprising:
forming a first buffer layer on the first interconnect; and
forming a second buffer layer on the photoelectric conversion layer.

14. The method according to claim 11, wherein the forming the third interconnect includes making a face of the third interconnect substantially flat, the face of the third interconnect being to contact the first interconnect.

15. A photoelectric conversion structure, comprising a plurality of photoelectric conversion elements,
each of the photoelectric conversion elements including:
a first interconnect;
a second interconnect separated from the first interconnect;
a photoelectric conversion layer provided between the first interconnect and the second interconnect; and
an insulating layer arranged with the first interconnect,
a face formed by the first interconnect and the insulating layer being substantially flat, the face contacting the photoelectric conversion layer,
the photoelectric conversion elements being connected in series to each other.

16. The structure according to claim 15, further comprising a third interconnect provided in a portion in which the photoelectric conversion elements are not linked to each other,
a part of the first interconnect of at least one of the photoelectric conversion elements being provided on the third interconnect.

17. The structure according to claim 16, further comprising a fourth interconnect provided in a portion in which the photoelectric conversion elements are linked to each other,
a part of the first interconnect of at least one of the photoelectric conversion elements being provided on the fourth interconnect.

18. The structure according to claim 15, wherein a thickness of the first interconnect is thicker than a thickness of the second interconnect.

19. The structure according to claim 15, further comprising:
a first buffer layer provided between the first interconnect and the photoelectric conversion layer; and
a second buffer layer provided between the second interconnect and the photoelectric conversion layer.

20. The structure according to claim 16, wherein a sheet resistance of the third interconnect is lower than a sheet resistance of the first interconnect.
